(19) United States
(12) Patent Application Publication
(10) Pub. No.: US 2011/0262765 A1
(43) Pub. Date: Oct. 27, 2011

(54) Process of metal plate press-formation with a fine line pattern and method of forming a fine line pattern on a molding die

(76) Inventors: Shih-Pu Yu, Taoyuan (TW); Jui-Hung Yang, Taoyuan (TW)

(21) Appl. No.: 12/833,002

(22) Filed: Jul. 9, 2010

(30) Foreign Application Priority Data
Apr. 27, 2010 (TW) 099113246

(51) Int. Cl. B32B 3/30; H05K 5/00; B44C 1/24; C23C 22/73; C23C 22/78; C23F 1/00; B44C 1/22

(52) U.S. Cl. 428/600; 216/41; 148/240; 101/32

(57) ABSTRACT

A metal plate press-forming process with a fine line pattern, in which the metal plate is heated and applied with a gas or liquid pressure in several stages so as to be pressed against a molding die to be formed into a shape and simultaneously to obtain a second fine-line pattern transferred from a first fine-line pattern on the molding die. A press-formed metal housing obtained using the aforesaid metal plate press-forming process is also disclosed. Also, a method of forming a fine line pattern on a molding die is disclosed, in which a patterned photoresist layer is formed on a block, and a fine line pattern on the block is formed by etching the block using the patterned photoresist layer as a mask.

### BACKGROUND OF THE INVENTION

1. Field of the Invention

The present invention relates to a process of metal plate press-formation, and particularly a process of metal plate press-formation with a fine line pattern simultaneously formed on the metal plate through heating and multi-staged pressing.

2. Description of the Prior Art

Metal housings of electronic products are conventionally manufactured by punch press. For example, a metal plate is punch-pressed by a male die and a female die to obtain a housing outline. However, in such process, the metal plate tends to be damaged at the bending of the housing profile. Gas compression formation is thus developed. It may be used for mass production, but it is limited to housing outline formation only. When a fine line pattern is desired on the housing surface, it must be made in a following process, for example, an etching process to etch the already formed metal housing. JP application publication No. 2004249320 discloses a method to manufacture a magnesium alloy product. An embodiment is shown by FIG. 1. A magnesium alloy plate 1 which is placed within a die 2 including a molding die 3 and a sealing die 4 is pressed therebetween. The molding die 3 has a cavity 5 and a gas outlet 6. After the magnesium alloy plate 1 is heated, a compressed gas control valve 9 is opened to allow compressed gas to flow through a compressed gas pipe 8 and blow to a space between the magnesium alloy plate 1 and the sealing die 4 from the compressed gas channel 7, so as to bulge the magnesium alloy plate 1 toward the molding die 3. Thereafter, a cooling liquid control valve 14 is opened to allow the cooling liquid to flow through a cooling liquid pipe 15 and spray to the magnesium alloy plate 1 from a cooling liquid channel 13, so as to quench the magnesium alloy plate 1. In such manner, the constitution of the magnesium alloy plate 1 may change and be rendered improved ductility according to the disclosure. It is preferred to carry out the step of cooling liquid spray after the compressed gas control valve 9 is closed and the vacuum valve 10 is opened, for preventing the cooling liquid from vaporization. If the cooling liquid is vaporized, the space between the magnesium alloy plate 1 and the sealing die 4 will be over-pressured. Thereafter, the vacuum valve 10 is closed, and the magnesium alloy plate 1 is heated again. Then, a compressed gas control valve 9 is opened again to pressurize the space between the magnesium alloy plate 1 and the sealing die 4, so as to bulge the magnesium alloy plate 1 toward the molding die 3. As a result, the magnesium alloy plate 1 can completely attach on the molding die 3. Thereafter, the vacuum valve 10 is opened to discharge the compressed gas, and a gas-compression formed product is obtained after the die 2 is opened. Press-formation, but not fine line pattern formation on surface of a product, is taught.

Therefore, there is still a need for a novel method of shaping a metal plate, in which fine line patterns can be simultaneously formed on the metal plate conveniently and economically.

### SUMMARY OF THE INVENTION

An object of the present invention is to provide a process of metal plate press-formation with a fine line pattern and a press-formed metal housing obtained therefrom. Fine line patterns can be formed simultaneously with formation of the metal housing, and accordingly the process is convenient and economical.

In another aspect, another object of the present invention is to provide a method of forming a fine line pattern on a molding die. The molding die with a fine line pattern thus obtained can be utilized for the process of metal plate press-formation with a fine line pattern of the present invention.

The process of metal plate press-formation with a fine line pattern according to the present invention includes steps as follows. First, a metal plate is placed in a molding device. The molding device includes a sealing die and a molding die. The molding die has a housing-shaped surface. The housing-shaped surface includes a first fine line pattern formed by etching. Next, the metal plate is heated and allowed to be pressed against the surface of the molding die to form a shape through a multistage gas compression or liquid compression, and the first line pattern is simultaneously imprinted onto the metal plate to form a second line pattern. Thereafter, a punching process is performed on the press-formed metal plate to give a press-formed article.

A press-formed metal housing according to the present invention is made by a method of metal plate press-formation with a fine line pattern as aforesaid.

The method of forming a fine line pattern on a molding die according to the present invention includes steps as follows. A block is provided. A patterned photoresist layer is formed on the block. The patterned photoresist layer has at least an opening exposing the underlying block. An etching process is performed on the block using the patterned photoresist layer as a mask to partially remove the block exposed from the at least an opening to form a fine line pattern on the block.

Compared with conventional techniques, in the process of metal plate press-formation with a fine line pattern according to the present invention, superplastic forming technique is employed. Different from conventional one, such as aluminum punch-press, the present invention utilizes gas or liquid compression, and, accordingly, the molding device has a simple design and is in a low cost. Moreover, the surface of the molding device has a fine line pattern formed by etching, and a metal plate having good forming or shaping properties is utilized. When the metal plate is press-formed, the fine line pattern on the molding device can be simultaneously transferred onto the metal plate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view illustrating a conventional method of making a magnesium alloy product;

FIG. 2 is a flow chart illustrating an embodiment of the process of metal plate press-formation with a fine line pattern according to the present invention;

FIGS. 3 and 4 are schematic cross-sectional views illustrating die opening and die closure respectively in an embodiment of the process of metal plate press-formation with a fine line pattern according to the present invention;

FIG. 5 is a schematic exploded view illustrating a molding device after a metal plate is press-formed in an embodiment of the process of metal plate press-formation with a fine line pattern according to the present invention;

FIG. 6 is a schematic cross-sectional view illustrating pressure application in an embodiment of the process of metal plate press-formation with a fine line pattern according to the present invention;

FIG. 7 is a schematic plan view illustrating a press-formed metal housing made from an embodiment of the process of metal plate press-formation with a fine line pattern according to the present invention;

FIG. 8 is a flowchart illustrating an embodiment of the method of forming a fine line pattern on a molding die according to the present invention;

FIG. 9 is a schematic view illustrating an embodiment of the method of forming a fine line pattern on a molding die according to the present invention; and

FIG. 10 is a schematic view illustrating another embodiment of the method of forming a fine line pattern on a molding die according to the present invention.

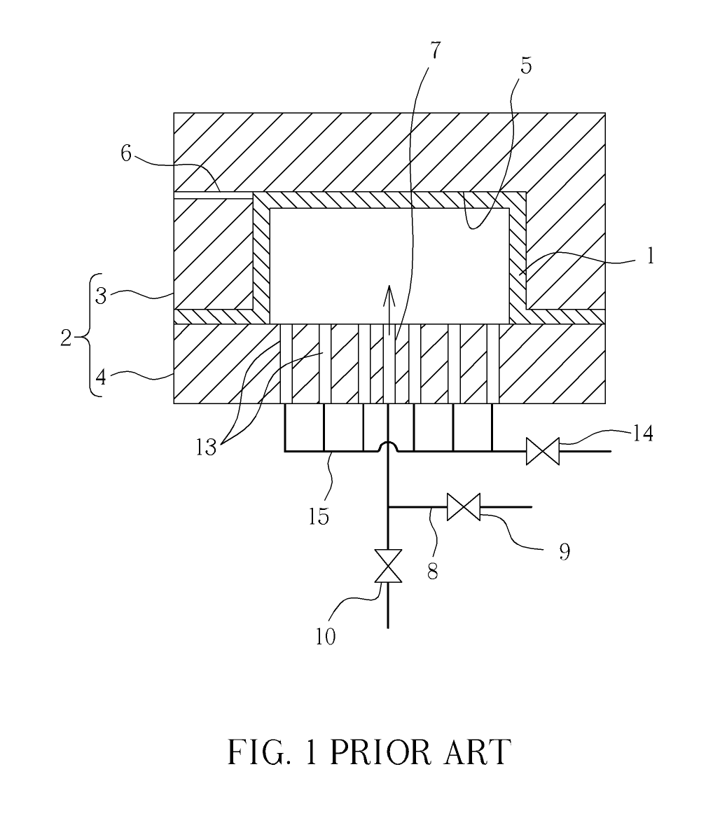

### DETAILED DESCRIPTION

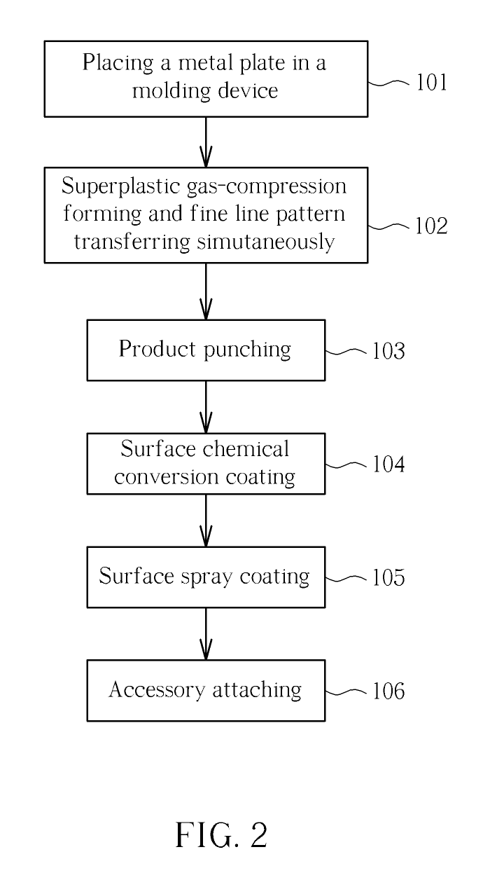

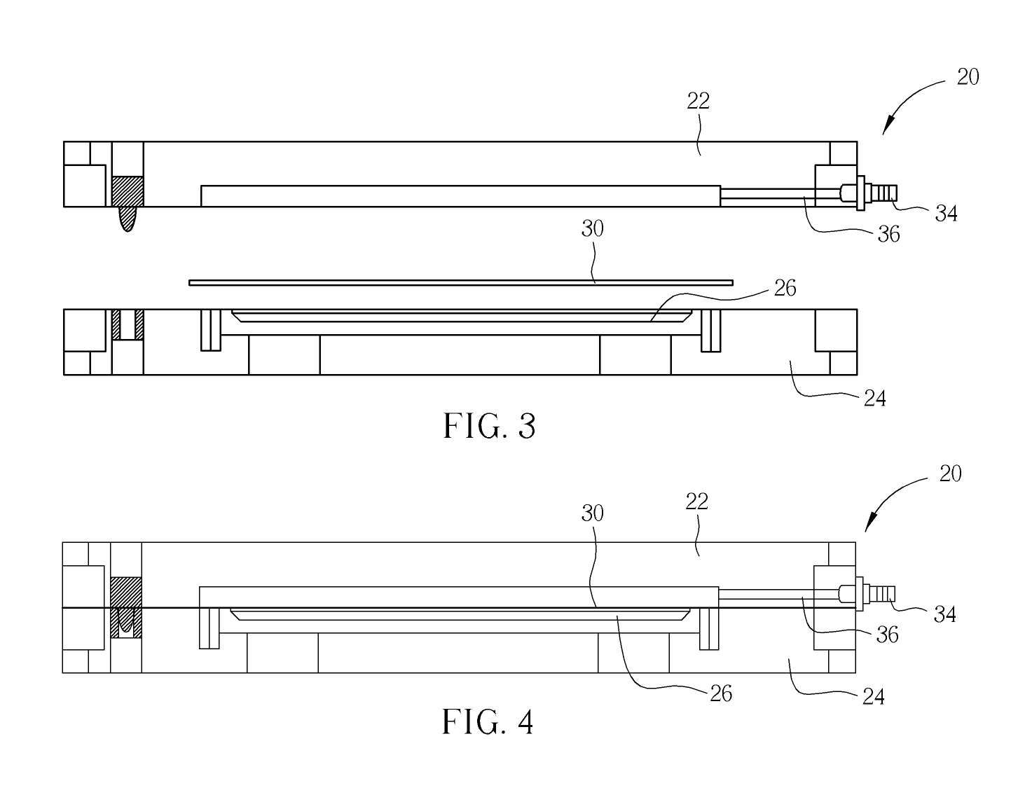

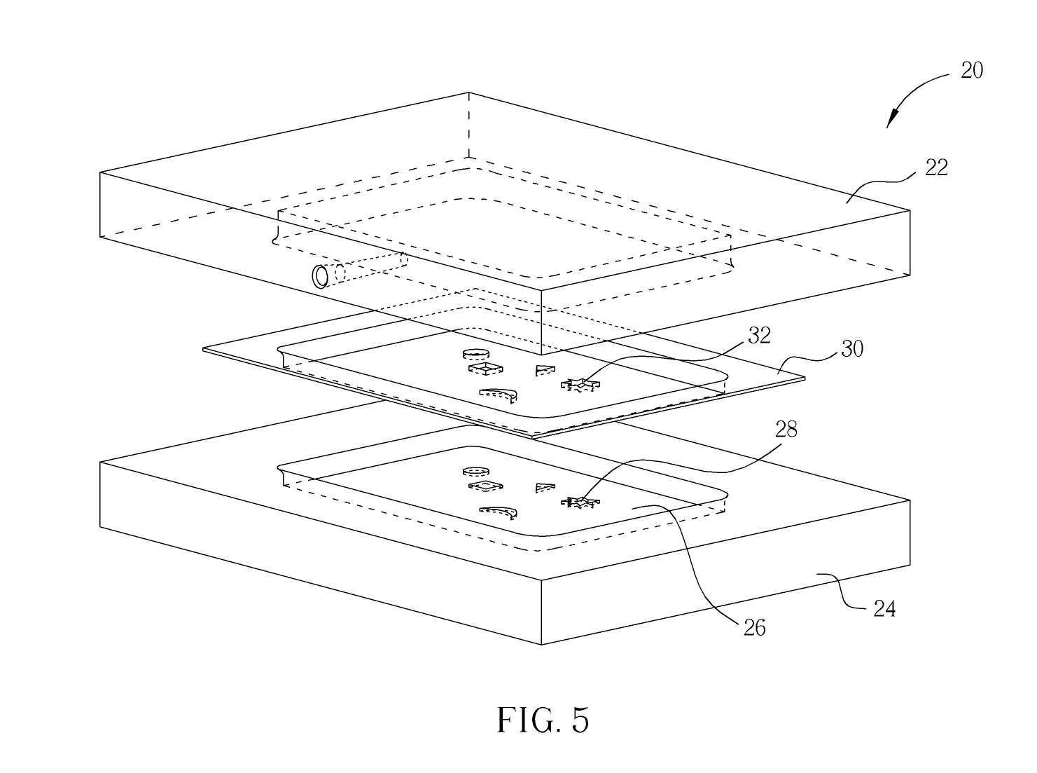

The process of metal plate press-formation with a fine line pattern according to the present invention can be illustrated by the flow chart in FIG. 2. First, Step 101 is performed to place a metal plate in a molding device. The metal plate is a kind of metal plate which can be easily formed into a desired shape upon being heated and pressed. The metal plate may include a metal or an alloy, such as magnesium alloy, and particularly such as AZ31 and AZ91, but is not limited thereto. An embodiment of the molding device can be referred to FIGS. 3 and 4, which show the die opening and die closure, respectively. FIG. 5 is a schematic exploded view illustrating an embodiment of a molding device after a metal plate is press-formed. The molding device 20 includes a sealing die 22 and a molding die 24. The molding die 24 has a surface 26 having a housing shape. The surface 26 is not limited to being a concave or a convex. In the drawings, it is a concave. The surface 26 further comprises a first fine line pattern 28 formed by etching. The metal plate 30 is placed between the sealing die 22 and the molding die 24, followed by die closure. Herein, the term “line” may be not limited to a straight line or a curved line.

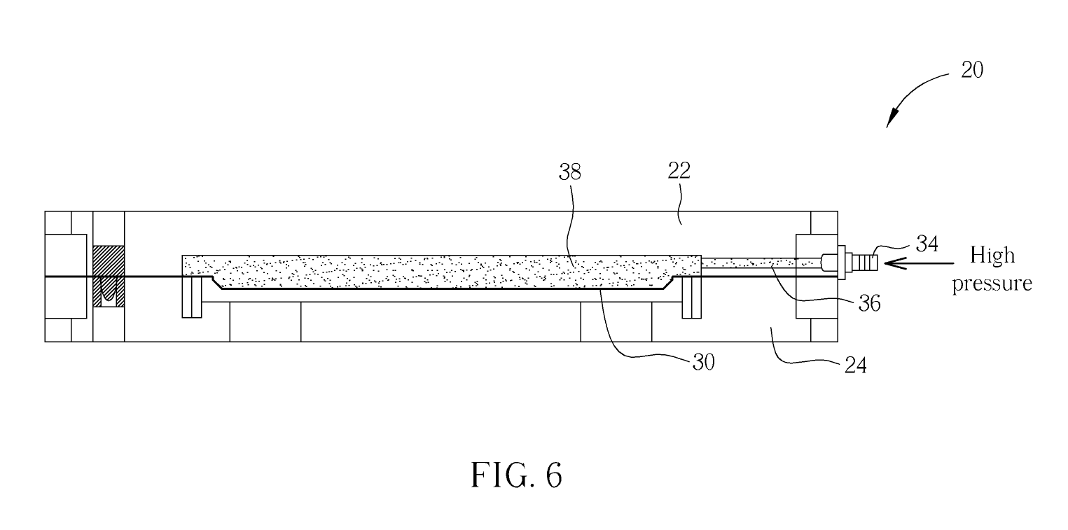

Next, Step 102 of superplastic gas-compression formation and fine line pattern transferring are simultaneously performed. In more detail, referring to FIGS. 5 and 6, the metal plate 30 is heated and allowed to be pressed against the surface 26 of the molding die to form a shape through a multistage gas compression or liquid compression. During this step, the first line pattern 28 is simultaneously imprinted onto the metal plate 30 to form a second line pattern 32. The heating temperature is related to the material of the metal plate 30, the pressure used for the gas compression or liquid compression, and the stage number for the multistage compression. The heating device may be combined with the external surface of the molding device 20. For example, the heating device may be a heating coil or a heating plate, but not limited thereto, to heat the die, in turn to heat the metal plate 30 inside the die.

A high pressurized gas or liquid may be supplied by a compressor with a pipe connected with an inlet 34 of the sealing die 22 and enter the cavity of the sealing die 22 from the inlet 34 passing a channel 36. The high pressurized gas or liquid 38 presses the metal plate 30 and forces the metal plate 30 against the surface 26 of the molding die 24 to form a metal housing.

Thereafter, Step 103 of product punching is performed to punch out the press-formed metal plate 30 in a desired outline, to obtain a press-formed article.

After Step 103, Step 104 of surface chemical conversion coating is optionally performed in a conventional manner to form a coating on the surface of the press-formed article. The coating may have a protection function. Thereafter, Step 105 of surface spray coating is optionally performed in a conventional manner to improve pleasing appearance. Thereafter, Step 106 of accessory attachment is optionally performed to attach accessories on press-formed articles. The accessories may be for example bosses, buckles, and the like, for assembly electronic devices including the press-formed articles.

Furthermore, a hot press-formed metal plate just obtained from the press-formation may be optionally placed onto a shape-fixing jig for cooling, so as to further shape the press-formed article, for example, allowing it to bear a flat surface or a lightly curved surface.

In the molding device 20, the sealing die 22 and the molding die 24 may be combined vertically or horizontally, whatever which is on the top or the left, and not particularly limited thereto. The housing-shaped surface of the molding die 24 is not limited to be a concave or a convex. If it is a concave, the resulting fine line pattern, which is transferred onto the convex surface of the metal housing formed by pressing the metal plate against this concave, may be clearer, relative to the fine line pattern formed on the concave surface of the metal housing. If it is a convex, the resulting fine line pattern, which is transferred onto the concave surface of the metal housing formed by pressing the metal plate against this convex, may be relatively deep and clearer, and the resulting fine line pattern, which is transferred onto the other side, i.e. the convex surface of the metal housing, may be relatively shallow.

The molding die 24 may be a singular die body having a desired housing surface or may further include a plurality of die core blocks in the die body and these die core blocks together form a desired housing surface. In the case of the plurality of die core blocks, the first fine line pattern formed by etching may be located on one or more of these die core blocks.

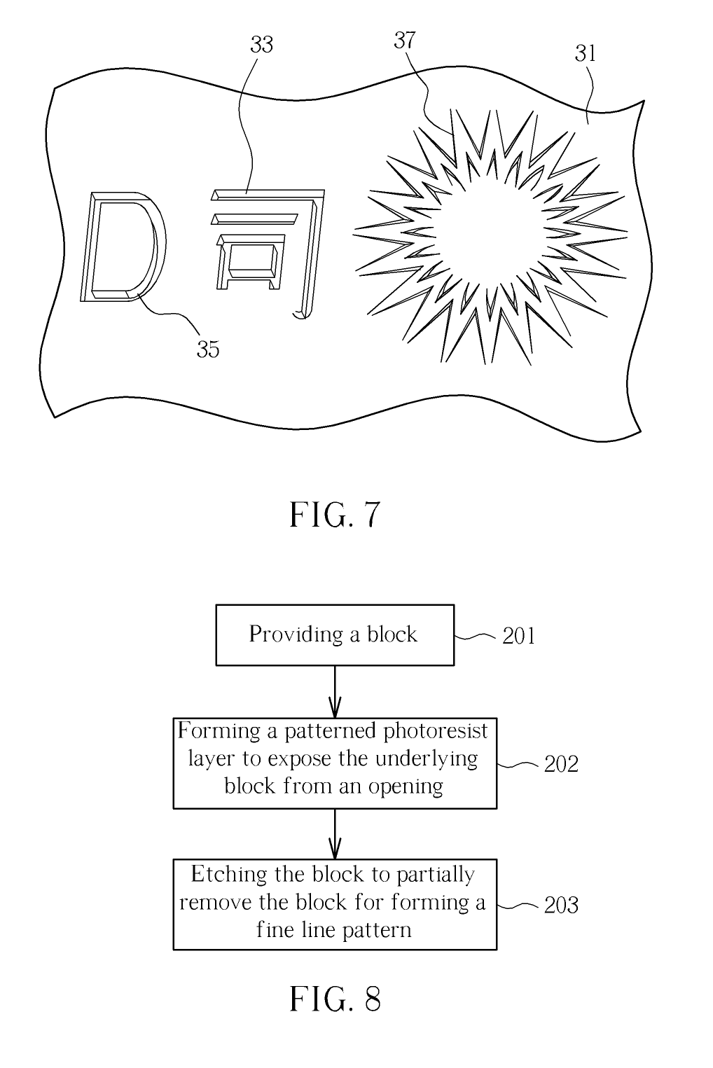

FIG. 7 illustrates an embodiment of a press-formed metal housing (i.e. press-formed article) made from a process of metal plate press-formation with a fine line pattern according to the present invention. It is shown that the press-formed metal housing 31 has a surface having a fine line pattern, in which a 4 mm-high character 33 and a 3 mm-high letter 35 can be clearly transferred. And a pointed shape 37 also can be transferred.

In another aspect, the method of forming a fine line pattern on a molding die for use in the process of metal plate press-formation with a fine line pattern is described in detail, referring to the flow chart shown in FIG. 8. First, Step 201 is performed to provide a block, which may be a singular die body to serve as the molding die, one of the die blocks composing of the molding die, or one of the die core blocks. Metal, such as steel, is preferred. High-temperature and high-pressure resistant one is more preferred. For example, NAK80, STAVAX or steel having a hardness of 40 to 50 is resistant to high heat up to 500° C. and high pressure up to 150 kg/cm². Next, Step 202 of forming a patterned photoresist layer to expose the underlying block from an opening is performed. In detail, a photoresist layer may be formed on the block using a photoresist. The photoresist layer is then exposed and developed to form a patterned photoresist layer. The patterned photoresist layer has one or more openings to expose the underlying block. Thereafter, Step 203 of etching is performed, i.e. to perform an etching process on the block using the patterned photoresist layer as a mask to partially remove the block where is exposed from the openings to forma fine line pattern on the block.

The final depth of the fine line pattern may be controlled by etching duration and etching frequency in the etching process. When the etching duration is longer or the etching frequency is higher, the etching extent of the block is more and the resulting line pattern is deeper. After a plurality of runs of the etching, a steep three-dimensional corner (having a steep slope) of the fine line pattern may become a smooth three-dimensional corner (having a gentle slope). Etching in several times also helps preventing undercut. The fine line pattern to be formed using such etching manner may be determined as desired. For example, using the process of metal plate press-formation with a fine line pattern according to the present invention, the line width may be down to 0.15 mm, when the depth of the line is 0.1 mm, and the line width may be down to 0.05 mm when the depth of the line is 0.05 mm. Both result in excellent pattern transferring. In other words, the depth of the fine line pattern of the molding die can be 0.05 mm to 0.10 mm and the width can be 0.05 mm to 0.15 mm in the process of the present invention.

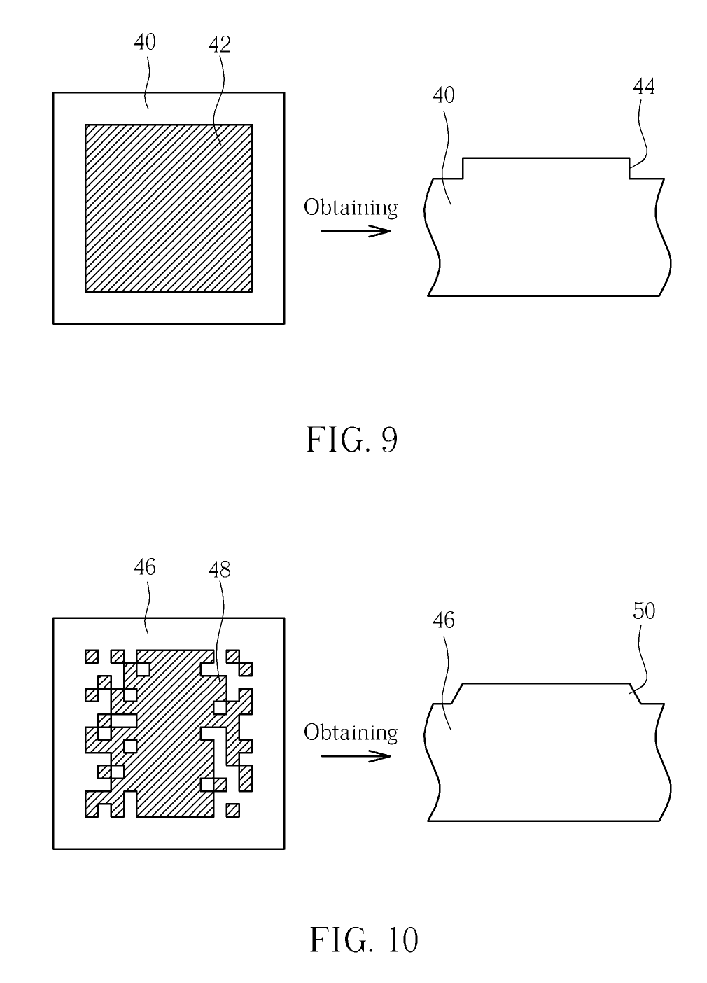

Furthermore, the patterned photoresist layer may have a pattern having a distinct edge, or it may have a pattern comprising plaid-like pixels and the density of the plaid-like pixels at the edge of pattern is gradually changed. In the former situation, as shown in FIG. 9, the patterned photoresist layer 42 on the block 40 shown by the plan view is a pattern having a distinct or sharp edge, such that, after the block 40 is etched, the resulting fine line pattern 44 has a steep edge as shown by the cross-sectional view. Accordingly, the fine line pattern obtained on the press-formed product also has a steep edge. In the latter situation, as shown in FIG. 10, the patterned photoresist layer 48 on the block 46 shown by the plan view is a pattern in which the density of the plaid-like pixels at the edge of the pattern is gradually changed, by virtue of which, the diffusion of the etchant on the surface of the block can be controlled, thereby to result a various etching extent, such that, after the block 46 is etched, the resulting fine line pattern 44 has a gentle edge (i.e. a gentle slope or a gradually increased height or depth) as shown by the cross-sectional view, or the line pattern has a curved sidewall. Accordingly, the fine line pattern obtained on the press-formed product also has a gentle edge or a curved sidewall. This kind of pattern for symbols on keys may enhance stereo visual effect. This is also a unique feature of the process of the present invention.

Moreover, before the etching process is performed on the block, a high pressure and a high heat may be applied to the block, and, thereafter, the block is ground to attain a designed size, so as to avoid an error in the designed size when the product expands upon being heated during use.

In a specific embodiment, a 0.5 mm thick AZ31 magnesium alloy plate was heated at a temperature in a range from 350° C. to 450° C. and press-formed under a gas pressure gradually rising from 0 to 150 kg/cm² in 20 stages. The line width of the fine line pattern of the molding die is 0.15 mm and the line depth is 0.1 mm. Thus the resulting press-formed article has a fine line pattern replication ratio of 80%.

Those skilled in the art will readily observe that numerous modifications and alterations of the device and method may be made while retaining the teachings of the invention.

What is claimed is:

1. A process of metal plate press-formation with a fine line pattern, comprising:
placing a metal plate in a molding device comprising:
a sealing die, and
a molding die having a housing-shaped surface comprising a first fine line pattern formed by etching;
heating the metal plate and allowing the metal plate to be pressed against the surface of the molding die through a multistage gas compression or liquid compression to form a shape, wherein the first line pattern is simultaneously imprinted onto the metal plate to form a second line pattern; and
performing a punching process on the press-formed metal plate to give a press-formed article.

2. The process of claim 1, wherein the molding die comprises a plurality of die core blocks together having the housing-shaped surface, and the first fine line pattern formed by etching is located on a surface of at least one of the die core blocks.

3. The process of claim 1, further comprising forming a surface chemical conversion coating layer on a surface of the press-formed article.

4. The process of claim 3, further comprising spray-coating a coating layer on the surface chemical conversion coating layer.

5. The process of claim 4, further comprising disposing a boss on the press-formed article.

6. The process of claim 1, wherein the first fine line pattern has a gentle edge.

7. The process of claim 6, wherein the second fine line pattern has a gentle edge.

8. The process of claim 1, wherein the housing-shaped surface of the molding die is a concave surface and the metal plate is pressed against the concave surface.

9. The process of claim 1, wherein the housing-shaped surface of the molding die is a convex surface and the metal plate is pressed against the convex surface.

10. The process of claim 1, further comprising delivering the hot press-formed metal plate from the molding device to a shape-fixing jig for cooling.

11. A press-formed metal housing made by a method of metal plate press-formation with a fine line pattern as recited in claim 1.

12. A method of forming a fine line pattern on a molding die, comprising:
providing a block;
forming a patterned photoresist layer on the block, wherein the patterned photoresist layer has at least an opening exposing the underlying block; and
performing an etching process on the block using the patterned photoresist layer as a mask to partially remove the exposed block to form a fine line pattern on the block.

13. The method of claim 12, wherein the fine line pattern has a depth determined by etching duration and etching frequency in the etching process.

14. The method of claim 13, wherein, repeating etching in the etching process on the block for a plurality of times to allow the fine line pattern to have a smooth three-dimensional corner.

15. The method of claim 12, further comprising, before performing the etching process on the block, a step of heating and grinding the block to a designed size.

16. The method of claim 12, wherein, the patterned photoresist layer comprises a pattern comprising plaid-like pixels having a gradually-changed distribution density.

17. The method of claim 16, wherein, the fine line pattern formed on the block has an edge being a gentle slope.

18. The method of claim 12, wherein, the molding die is a die core block.
